(19) United States
(12) Patent Application Publication
(10) Pub. No.: US 2026/0238525 A1
(43) Pub. Date: Aug. 13, 2026

(54) Method for generating a signal, method for constructing a basic sequence, corresponding device and computer program

(71) Applicant: UNIVERSITÉ DE BRETAGNE SUD, Lorient (FR)

(72) Inventors: Emmanuel BOUTILLON, LORIENT (FR); Cédric MARCHAND, Quéven (FR)

(21) Appl. No.: 19/153,011

(22) PCT Filed: Feb. 1, 2024
(86) PCT No.: PCT/EP2024/052490

§ 371 Date: Aug. 1, 2025

(30) Foreign Application Priority Data
Feb. 2, 2023 (FR) FR2300964
Feb. 2, 2023 (FR) FR2300973

(51) Int. Cl. H04L 27/20

(52) U.S. Cl. CPC H04L 27/2032

(57) ABSTRACT

A method for generating a signal which is implemented in a digital communications system. The method includes: obtaining a basic sequence of q complex values, noted as B, such that the autocorrelation function R_{BB} of the basic sequence B satisfies

$${R}_{BB} ( τ = iq / c ) = {e}^{- \frac{2 j π hi}{c}} {R}_{BB} ( 0 ) ,$$

for i∈{0, . . . , c−1} and R_{BB}(τ)=0 otherwise; selecting Λ subsequences of p complex values in the basic sequence B; and using at least one of the selected subsequences to generate the signal.

### 1. FIELD OF THE INVENTION

The field of the invention is digital communications.

More specifically, the invention relates to the determination of a sequence of complex values with particular properties and to the use of said sequence in communication systems.

The invention has applications in particular in the field of wireless communications (for example, using radio waves or unguided optical waves) or wired communications (for example, using optical fibre or electrical cable). In particular, the invention has applications in the field of IoT (Internet of Things) communications.

### 2. PRIOR ART

In order to improve the robustness of communications via a communication channel, it is known to use error-correcting codes. For example, LDPC (Low-Density Parity Check) codes, turbo codes, polar codes, and Reed-Solomon codes provide good performance in terms of error correction.

In the document “Non-Binary Low-Density Parity-Check coded Cyclic Code-Shift Keying” (2013 IEEE Wireless Communications and Networking Conference (WCNC)), E. Boutillon et al. proposed associating a non-binary LDPC-type error correction code with a cyclic code-shift keying (CCSK) modulation.

As illustrated in FIG. 1, such a coding scheme takes a source message as input. For example, the source message has a size of k×m bits, where each m-uplet of bits corresponds to a symbol of a Galois field of cardinality q=2^{m}, noted as GF(q). In a first coding step 11, the k symbols of the source message are encoded by a non-binary LDPC (NB-LDPC) code with a code rate rₒ=k/n, also known as the outer code. A code word output by the NB-LDPC encoder 11 thus includes n symbols belonging to GF(q), i.e. n×m bits.

Each of the symbols GF(q) of the code word is then encoded in a second modulation step 12 by a CCSK code with a code rate rᵢ=m/q, also known as the internal code. Thus, each symbol GF(q) of the code word (represented by m bits) can be encoded, or modulated, by a sequence of q bits.

A BPSK (Binary Phase-Shift Keying) modulation can then be implemented in a third step 13 in order to transmit n cyclically offset versions of the sequence of q bits which are respectively associated with a symbol GF(q) of the code word.

More specifically, the CCSK modulation step 12 can implement different steps. In particular, a bijection can be defined between the q elements (0, α⁰, . . . , α^{q-2}) defined in the Galois field GF(q) and q integers between 0 and q−1 (0, 1, 2, . . . , q−1). Such a bijection allows the elements of GF(q) and the integers between 0 and q−1 to be represented indifferently.

A basic binary sequence of size q, noted as B, also known as the basic sequence, can then be defined: B={B(i)}_{i=0 . . . ,q-1}, wherein B(i)∈{0,1}. Such a sequence can in particular be pseudorandom.

The CCSK modulation 12 in particular associates the a^{th} element of GF(q) with the binary sequence Bₐ defined by a circular rotation (or cyclic offset) of a positions on the basic binary sequence B:Bₐ={B(i−a mod q)}_{i=0, . . . ,q-1}.

For example, if q=8 and the basic binary sequence B is defined by B=(1, 0, 0, 1, 1, 1, 0, 0), then the first symbol of GF(8) is associated with the sequence at B₁=(0, 0, 1, 1, 1, 0, 0, 1), the second symbol of GF(8) is associated with the sequence B₂=(0, 1, 1, 1, 0, 0, 1, 0) and so on. The example given relates to a circular rotation or a cyclic shift to the left. It is possible, symmetrically, to define a circular rotation or a cyclic shift to the right.

In order to increase the spectral efficiency of the inner code (with the code rate rᵢ=m/q in the above example), the document “Rate-adaptive Inner Code for Non-Binary Decoders”, C. Marchand et al. (11th International Symposium on Topics in Coding, 2021) proposed to truncate the CCSK modulation to the first p bits, p≤q, in order to adapt the rate to transmission conditions. The code rate rᵢ of the internal code in this case is rᵢ=m/p.

For a truncation of size p, the a^{th} element of GF(q) can then be encoded/modulated by a binary sequence

$${B}_{a}^{p}$$

defined by

$${B}_{a}^{p} = ( B ( a ) , B ( a + 1 ) , ... , B ( a + p - 1 ) )$$

with the operations on the indices performed modulo q. In the following, the set of sequences

$${B}_{a}^{p}$$

of a length p such that a∈{0, . . . , q−1} is called B^{p}.

In the above examples, the basic sequence considered is a binary sequence. It is also possible, however, to use non-binary basic sequences for CCSK modulations. Such non-binary basic sequences are also known as NB-CCSK, or q-ary CCSK. Just like binary CCSK sequences, q-ary CCSK sequences can be truncated.

By way of example, FIG. 2A illustrates a transmission scheme that combines a Non-Binary code with a Truncated Non-Binary CCSK modulation (NB-TCCSK).

Such a coding scheme takes as input a source message including k information symbols of a Galois field of cardinality q=2^{m}, noted as GF(q). The source message thus has a size of k×m bits, where each m-uplet of bits corresponds to a symbol of GF(q). In a first step, the k information symbols of the source message, for example (α⁰, α³, α⁷, α²) with k=4, are encoded by a non-binary NB code. The resulting code word includes n symbols of GF(q), i.e. a code word of size n×m bits, for example (α⁰, α³, α⁷, α², α¹, α⁴, α⁰, α⁵, α², α⁶, α³, α⁴) with n=12. The coding rate of the external code is thus

$${r}_{o} = \frac{k}{n} , for example {r}_{o} = \frac{1}{3} .$$

In a second step, each symbol of the code word is encoded by the internal code. The internal code uses a Truncated Non-Binary CCSK modulation (NB-TCCSK).

Thus, each symbol GF(q) of the code word (represented by m bits) can be encoded, or modulated, by a non-binary sequence of q elements, or “chips”. The non-binary sequence is constructed, for example, from integers from 0 to q−1, where each integer corresponds to a point on a constellation of size q (q-ary constellation). For example, if q=8, the first symbol α⁰ of the code word is associated with a first version of the non-binary sequence of 8 chips, for example with the sequence (0,1,6,7,4,5,2,3), according to a (spreading) rate rₛ=1/q=1/8. The following symbols (α³, α⁷, . . . ) can be associated with other versions of the non-binary sequence, which are defined by the circular rotation of the non-binary sequence of q chips (i.e. q versions).

After encoding a symbol of the code word, the resulting non-binary sequence of q chips can be truncated to p chips. For example, the sequence (0,1,6,7,4,5,2,3) of size q=8 is truncated to a sequence (0,1,6) of size p=3, according to a (truncation) rate rₜ=q/p=8/3.

Each chip (i.e. each element of the truncated sequence of size p) is then modulated using a modulation of size q, according to a (modulation) rate rₘ=log₂ (q), and then transmitted in a communication channel.

FIG. 2B illustrates the resulting truncated sequence (0,1,6), where each chip corresponds to a point on the 8-PSK constellation.

It is known that the quality of a modulation scheme depends on the distance between the constellation points. In the foregoing examples based on binary or non-binary, truncated or non-truncated CCSK modulation, the quality of the modulation scheme depends in particular on the minimum Euclidean distance between two sequences.

We turn in the following to the determination of the minimum Euclidean distance between two binary or non-binary sequences

$${B}_{a}^{p} and {B}_{b}^{p}$$

obtained by applying a circular rotation of a positions and b positions, respectively, to a basic sequence. If the basic sequence is not truncated, then p=q; if the basic sequence is truncated, then p<q; and if the basic sequence is extended, then p>q.

The square of the distance between the two sequences

$${B}_{a}^{p} and {B}_{b}^{p}$$

is defined as:

$${d ( {B}_{a}^{p} , {B}_{b}^{p} )}^{2} = {‖ {B}_{a}^{p} ‖}^{2} + {‖ {B}_{b}^{p} ‖}^{2} - 2 ℛ ( 〈 {B}_{a}^{p} , {B}_{b}^{p} 〉 )$$

wherein

[symbol]

$$〈 {B}_{a}^{p} , {B}_{b}^{p} 〉$$

denotes the real part of the expression of the scalar product between the two sequences

$${B}_{a}^{p} and {B}_{b}^{p} , and {‖ {B}_{a}^{p} ‖}^{2} and {‖ {B}_{b}^{p} ‖}^{2}$$

denote the squared magnitudes of the vectors

$${B}_{b}^{p} ,$$

respectively. In the case where the points corresponding to the graphical representations of the complex values of the sequences

$${B}_{a}^{p} and {B}_{b}^{p}$$

are placed on the unit circle, then

$${‖ {B}_{a}^{p} ‖}^{2} = p and {‖ {B}_{b}^{p} ‖}^{2} = p i . e .$$

$${d ( {B}_{a}^{p} , {B}_{b}^{p} )}^{2} = 2 p - 2 ℛ ( 〈 {B}_{a}^{p} , {B}_{b}^{p} 〉 )$$

The minimum distance associated with this family B^{p} of sequences of size p (i.e. associated with the basic sequence and the different versions of the same obtained by circular rotation to the right or left) can thus be expressed in the following form:

$$D ( {B}^{p} ) = min \{ {d ( {B}_{a}^{p} , {B}_{b}^{p} )}^{2} \}$$

wherein a, b∈GF(q) and a≠b.

As indicated above, the CCSK modulation defines, in particular, a bijection between the q elements (0, α⁰, . . . , α⁹⁻²) defined in the Galois field GF(q) and q integers between 0 and q−1 (0, 1, 2, . . . , q−1). Consequently, a,b belong indifferently to GF(q) or to {0, . . . , q−1}.

This minimum distance can be normalized in order to obtain an average minimum distance per chip (per element/symbol):

$$\overline{D} ( {B}^{p} ) = \frac{D ( {B}^{p} )}{p}$$

If the points corresponding to the graphical representations of the complex values of the sequences

$${B}_{a}^{p} and {B}_{b}^{p}$$

are located on the unit circle, we can thus deduce:

$$\overline{D} ( {B}^{p} ) = 2 - \frac{2}{p} \times max \{ ℛ ( 〈 {B}_{a}^{p} \times {B}_{b}^{p} 〉 ) \}$$

wherein, a,b∈GF(q)² and a≠b

When the sequence is not truncated, i.e. p=q, it is possible to maximize D̅(B^{q}) using a CAZAC (Constant Amplitude Zero AutoCorrelation) sequence, for example a Zadoff-Chu sequence. For this type of sequence, the out-of-phase cyclic autocorrelations are equal to zero, i.e.

$$〈 {B}_{a}^{q} , {B}_{b}^{q} 〉 = 0$$

for a≠b. In the following, the normalized minimum distance is optimal where D̅(B^{p})=2.

However, these properties are no longer satisfied when the sequence is truncated, i.e. p<q.

By way of example, FIG. 3 illustrates the progression of the normalized minimum distance D̅(B^{p}) as a function of the size p of the sequence after truncation. If p=q=64, the normalized minimum distance is optimal with D̅(B^{p})=2. If p<q, the normalized minimum distance decreases and drops rapidly as p decreases.

There is thus a need for a new type of sequence which can be used in particular for the implementation of a non-binary CCSK modulation and which has good properties in terms of minimum distance, before or after truncation.

### 3. DESCRIPTION OF THE INVENTION

The proposed solution is based on a method for generating a signal which is implemented in a digital communications system and which includes the following steps:
obtaining a basic sequence of q complex values, noted as B, such that the autocorrelation function R_{BB} of said basic sequence B, which is defined by

$${R}_{BB} ( τ ) = {\sum }_{n = 0}^{q - 1} B ( n ) {B ( n + τ mod q )}^{*} ,$$

wherein B((n+τ)mod q)* denotes the complex conjugate of B((n+τ)mod q), and T=0,1, . . . , q−1, satisfies:

$${R}_{BB} ( τ = iq / c ) = {e}^{\frac{2 j π hi}{c}} {R}_{BB} ( 0 ) , for i ∈ \{ 0 , … , c - 1 \}$$

wherein q is a multiple of c, c>1, h and c are coprime integers, and j²=−1,
and:

$${R}_{BB} ( τ ) = 0 otherwise ,$$

selecting Λ subsequences of p (consecutive) complex values in said basic sequence B, such that said subsequence λ, noted as B_{λ}=B^{p}(s(λ)), wherein λ∈{0, . . . , Λ−1}, 1≤Λ, is equal to:

$${B}_{λ} = \{ B ( s ( λ ) ) , B ( s ( λ ) + 1 mod q ) , … , B ( s ( λ ) + p - 1 mod q ) \}$$

wherein s(λ) is an integer belonging to {0, . . . , q−1} corresponding to a position in said basic sequence B, and B(s(λ)) is the complex value associated with said position s(λ) in said basic sequence B,
using at least one of said selected subsequences to generate said signal.

According to the invention, a basic sequence with particular properties is used to generate subsequences that likewise have particular properties, in particular in terms of orthogonality or minimum distance. In particular, the generation of the basic sequence can be carried out in advance, and the basic sequence or sequences can be stored, for example, in a database that is internal to the entity implementing the following method, or that can be accessed by such an entity.

For example, if c=4, the representation of the autocorrelation function R_{BB} in the complex plane has a symmetry of order 4. The family including the basic sequence and at least one cyclically offset version of the basic sequence has a normalized minimum distance D̅(B) equal to 2, and the family including the selected subsequences also has a normalized minimum distance D̅(B^{p}) equal to 2 for certain values of p, in particular p=q/4, p=q/2, p=3q/4.

Thus, the basic sequence and its cyclically offset versions are orthogonal (as with Zadoff-Chu sequences). In addition, the selected subsequences have a minimum distance equal to 2p (which is not the case for truncated Zadoff Chu sequences).

It is thus possible to adapt the length p of the subsequence used in order to generate the signal according to the needs of the communication system.

It should also be noted that the basic sequence B has a size q, and the subsequence B_{λ} has a size p. In a particular embodiment, p<q. In this case, a subsequence is considered to be a truncation or a portion of the basic sequence or of a cyclically offset version of the basic sequence. In another embodiment, p=q. In this case, a subsequence is the basic sequence or a cyclically offset version of the basic sequence. In yet another embodiment, p>q. In this case, a global sequence was formed from the basic sequence and at least one partial repetition of the basic sequence, and a subsequence is a truncation or a portion of the global sequence.

In a particular embodiment, the cardinal of A is greater than or equal to 2, i.e. Λ≥2.

In a first example application, the subsequences are spreading sequences intended to be used by distinct terminals, or groups of terminals, of said communications system, for example during the implementation of an access protocol.

For example, the method according to one embodiment implements a step of allocating one of said selected subsequences to a terminal of said communications system and of transmitting said signal using the subsequence.

For example, a base station can generate a number of subsequences and allocate a distinct subsequence, or a subsequence identifier, to the terminals present in its coverage area. In a variant, a terminal in the communications system can allocate a subsequence from a set of subsequences obtained from the basic sequence to itself.

A terminal can then use the subsequence that it has been allocated for its communications with the base station, which makes it possible to resolve, or at the very least to limit, collision issues when a plurality of terminals wish to establish radio communication with the base station simultaneously.

Thus, a first user can use a first set of subsequences to modulate a first data signal, and a second user can use a second set of subsequences to modulate a second data signal. Even if the terminals of the two users should transmit the first data signal and the second data signal simultaneously, a decoder would be able to decode the different data signals thanks to the large distance between the subsequences.

The proposed solution in particular makes it possible to increase the number of users in the communications system. In fact, it is noted that according to the prior art, for instance for a Zadoff-Chu sequence of length q=16, it is possible to generate 16 orthogonal sequences of length q=16. According to the invention, for a basic sequence of length q=64, it is possible to generate 64 distinct subsequences of length p=16.

Now the greater the number of distinct sequences, the greater the number of users that can communicate simultaneously in the communications system.

In a second example application, said subsequences are code words of a dictionary intended to be used by an encoder of said communications system.

For example, the method implements the association of at least one coded symbol, obtained at the end of a step of encoding at least one source symbol, with one of the selected subsequences.

Such subsequences can be used in particular in a communications system that implements a coding scheme with a binary or non-binary encoder with a non-binary, truncated or non-truncated CCSK modulation.

The length p of the subsequences can in particular be chosen while taking into account the conditions of the transmission channel.

In particular, if the transmission channel has little noise or interference, the length of the subsequences can be reduced by choosing p<q, which increases the transmission rate. Conversely, if the transmission channel has a lot of noise and/or interference, the length of the subsequences can be increased so as to obtain a better immunity to noise and/or interference, with a corresponding decrease in the transmission rate. The rate is thus adaptive (“adaptive rate”).

In a particular embodiment, the basic sequence B is constructed based on the following steps:
obtaining an initial vector Θ comprising q/c real elements,
for each real element Θ(k) of said initial vector Θ, transforming said real element Θ(k) into a complex element Δ(k), according to the expression:

$$Δ ( k ) = {( cq )}^{1 / 2} {e}^{\frac{2 π jΘ ( k )}{q}} , wherein k ∈ \{ 0 , … , q / c - 1 \} and {j}^{2} = - 1 ,$$

determining a Kronecker product between the vector Δ formed from said complex elements Δ(k) and a binary vector A of size n_{A}=c, such that A(i=h)=1 and A(i+h)=0, wherein i∈{0, . . . , c−1}, h and c are coprime integers, which provides a basic vector X of size q,
transforming said basic vector X from the frequency domain to the time domain (for example, by implementing an Inverse Fast Fourier Transform of size q), which provides said basic sequence B of q complex values.

In particular, it should be noted that the multiplicative coefficient (cq)^{1/2} used in determining the vector Δ makes it possible to obtain a basic sequence B having, on average, components whose energy (i.e. the square of their modulus) is equal to 1. We thus obtain |B∥²=q directly by design.

Such steps in particular make it possible to construct deterministically, in the frequency domain, a basic sequence and subsequences with good properties in terms of orthogonality or minimum distance.

It is noted that the Kronecker product between the vector Δ of size n=q/c and the binary vector A of size n_{A}=c yields the vector X=Kronecker(Δ, A) of size n_{X}=n_{Δ}×n_{A}=q, with X(k), k=δn_{A}+a given by X(k)=Δ(δ)×A(a), wherein δ∈{0, . . . , n_{Δ}−1} and a∈{0, . . . , n_{A}−1}.

According to a first example, the q/c real elements of said initial vector Θ are chosen randomly.

According to a second example, the q/c real elements of said initial vector Θ are chosen so that the points corresponding to the graphical representations of the q complex values of the basic sequence B belong to at least one circle, for example the unit circle (q-PSK “Phase-Shift Keying” modulation) or to concentric circles (q-APSK “Amplitude and Phase-Shift Keying” modulation).

This makes it easier to modulate the subsequence or the signal obtained from the subsequence.

The basic sequence, or a subsequence obtained from the basic sequence, can thus be based on a q-APSK modulation (e.g., 16 APSK or 32 APSK).

According to a particular embodiment, with c=4, a modified initial vector Θ′ is obtained by adding a vector V of size q/c, which is known as the added vector, and the initial vector Θ of q/c real elements, wherein said added vector V is equal to ν×N, wherein ν∈[1, q−1] and N is a vector of size q/c constructed by choosing its q/(2c) first elements in the set {−1,0,1}, then copying the q/(2c) first elements so that N(i)=N(i+q/(2c)), i=0,1, . . . , q/(2c)−1.

It is thus possible to generate a basic sequence that maximizes the normalized minimum distance.

According to a particular embodiment, the selection step selects a subset of subsequences, noted as B^{λ}, of cardinality Λ, from the set B^{p} of subsequences of size p, such that said subset B^{λ} has the largest normalized minimum distance D̅(B^{λ}):

$$\overline{D} ( {B}^{λ} ) = \frac{{‖ {B}_{{λ}_{1}} ‖}^{2}}{p} + \frac{{‖ {B}_{{λ}_{2}} ‖}^{2}}{p} - \frac{2}{p} \times {max}_{{λ}_{1} , {λ}_{2} , {λ}_{1} \neq {λ}_{2}} \{ ℛ ( 〈 {B}_{{λ}_{1}} , {B}_{{λ}_{2}} 〉 ) \}$$

wherein [symbol] ( [symbol] B_{λ}_{₁}, B_{λ}_{₂} [symbol] ) denotes the real part of the expression of the scalar product between the subsequence B_{λ}_{₁} and the subsequence B_{λ}_{₂},λ₁,λ₂∈{0, . . . ,Λ−1}². In a particular embodiment, c is equal to 3, 4 or 5.

For example, if c=3, then A=[010] or A=[001]. If c=4, then A=[0100] or A=[0001]. If c=5, then A=[01000], A=[00100], A=[00010] or A=[00001].

In particular, when c is equal to 3 or 4, the normalized minimum distance for the basic sequence is optimal and is equal to 2, for the values p=q/3 and p=2q/3, or p=q/4, p=q/2 and p=3q/4, respectively.

The representation in the complex plane of the autocorrelation function R_{BB} has a symmetry of order 3, 4 or 5, respectively.

The invention also relates to a method for constructing a basic sequence of q complex values, noted as B, intended for use in a digital communications system and implemented by a processor, characterized in that the autocorrelation function R_{BB} of said basic sequence B, which is defined by

$${R}_{BB} ( τ ) = {\sum }_{n = 0}^{q - 1} B ( n ) B ( ( n + τ ) mod q ) * ,$$

wherein B((n+τ)mod q)* denotes the complex conjugate of B((n+τ)mod q), and T=0,1, . . . , q−1, satisfies:

$${R}_{BB} ( τ = iq / c ) = {e}^{\frac{2 j π hi}{c}} {R}_{BB} ( 0 ) , for i ∈ \{ 0 , ¨ , c - 1 \}$$

wherein q is a multiple of c, c>1, h and c are coprime integers, and j²=−1,
and:

$${R}_{B B} ( τ ) = 0 otherwise .$$

In particular, such a basic sequence can be constructed in different ways, in particular in the time domain or in the frequency domain.

In another embodiment, the invention relates to a device for generating a corresponding signal.

Such a device includes at least one processor configured to implement the steps described in the foregoing.

Such a device is in particular adapted to implement the method for generating a signal or for constructing a basic sequence described in the foregoing. It is, for example, integrated into a base station or into a device for monitoring a communications system (allowing, for example, a spreading sequence to be assigned to each user), or into a terminal of the communication system.

This device can of course include the different features relating to the methods according to the invention, which can be combined or implemented separately. Thus, the features and advantages of this device are the same as those of the method described in the foregoing. They are thus not described in further detail.

The invention also relates to one or more computer programs including instructions for implementing a method as described above when this or these programs are executed by at least one processor.

The invention also relates to a computer-readable information medium containing instructions for a computer program as mentioned above.

### 4. LIST OF THE FIGURES

Other features and advantages of the invention will become clearer from a reading of the following description of a particular embodiment-intended simply as an illustrative and non-limiting example—and of the annexed figures, wherein:

FIG. 1 illustrates a coding scheme that associates a non-binary LDPC-type error-correcting code with a cyclic code-shift keying CCSK modulation according to the prior art,

FIG. 2A illustrates a transmission scheme that combines a non-binary error-correcting code with a Truncated Non-Binary CCSK modulation (NB-TCCSK) according to the prior art,

FIG. 2B illustrates an example of a truncated sequence obtained in the transmission scheme of FIG. 2A,

FIG. 3 shows the progression of the normalized minimum distance D̅(B^{p}) as a function of the size p of the sequence after truncation, according to the prior art,

FIG. 4 shows the main steps implemented by a method for generating a signal according to an embodiment of the invention,

FIG. 5 illustrates the main steps for constructing a basic sequence in the frequency domain,

FIG. 6A illustrates an example of the representation of a basic sequence with q=75, and FIG. 6B shows the progression of the normalized minimum distance D̅(B^{p}) as a function of the size p of the subsequences,

FIG. 7A illustrates another example of the representation of a basic sequence with q=75, FIG. 7B shows the progression of the normalized minimum distance D̅(B^{p}) as a function of the size p of the subsequences, and FIG. 7C illustrates the representation of the associated autocorrelation function in the complex plane,

FIG. 8 illustrates the representation of an example of a C4 sequence in the complex plane,

FIG. 9A and FIG. 9B illustrate examples of representations of C4 sequences with q=64,

FIG. 10A and FIG. 10B illustrate other examples of representations of C4 sequences with q=64,

FIG. 11 illustrates yet another example of a representation of a C4 sequence,

FIG. 12 shows the simplified structure of an entity of a communications system implementing a technique for generating a signal according to an embodiment of the invention.

### 5. DESCRIPTION OF AN EMBODIMENT OF THE INVENTION

### 5.1 General Principle

The general principle of the invention is based on the construction of a basic sequence of length q that has particular properties, and the use of this basic sequence, or of a subsequence of length p obtained from this basic sequence, in a digital communications system.

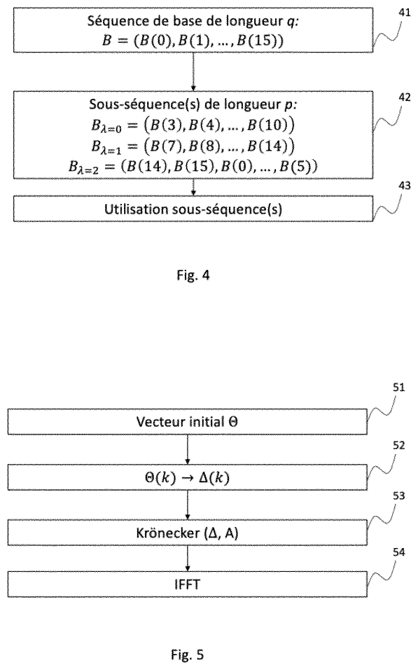

FIG. 4 shows the main steps implemented by a method for generating a signal according to an embodiment of the invention.

In a first step 41, a basic sequence of q complex values, noted as B, is obtained at the start of the method. In particular, the autocorrelation function R_{BB} of said basic sequence B, which is defined by

$$\begin{matrix}{R}_{BB} ( τ ) = {\sum }_{n = 0}^{q - 1} B ( n ) {B ( ( n + τ ) mod q )}^{*} = , τ = 0 , 1 , … , q - 1 , satisfies \\ {R}_{BB} ( τ = iq / c ) = {e}^{- \frac{2 j π hi}{c}} {R}_{BB} ( 0 ) , for i ∈ \{ 0 , ¨ , c - 1 \}\end{matrix}$$

wherein q is a multiple of c, c>1, h and c are coprime integers, and j²=−1,
and:

$${R}_{BB} ( τ ) = 0$$

Different techniques, which are explained in the following, can be used to construct such a basic sequence.

By way of example, the basic sequence is equal to B=(B(0), B(1), . . . , B(15)), with q=16.

In a second step 42, Λ subsequences of p complex values are selected in the basic sequence B, such that the subsequence λ, noted as B_{λ}=B^{p}(s(λ)), wherein λ∈{0, . . . , Λ−1}, 1≤Λ, is equal to:

$${B}_{λ} = {B}^{p} ( s ( λ ) ) = \{ B ( s ( λ ) ) , B ( s ( λ ) + 1 mod q ) , … , B ( s ( λ ) + p - 1 mod q ) \}$$

wherein s(λ) is an integer belonging to {0, . . . , q−1} corresponding to a position in said basic sequence B, and B(s(λ)) is the complex value associated with said position s(λ) in the basic sequence B.

For example, Λ=3 subsequences of p=8 complex values are selected in the basic sequence B.

$$\begin{matrix}{B}_{λ = 0} = {B}^{p} ( s ( 0 ) ) = \{ B ( s ( 0 ) ) , B ( s ( 0 ) + 1 mod q ) , … , B ( s ( 0 ) + p - 1 mod q ) \} \\ {B}_{λ = 1} = {B}^{p} ( s ( 1 ) ) = \{ B ( s ( 1 ) ) , B ( s ( 1 ) + 1 mod q ) , … , B ( s ( 1 ) + p - 1 mod q ) \} \\ {B}_{λ = 2} = {B}^{p} ( s ( 2 ) ) = \{ B ( s ( 2 ) ) , B ( s ( 0 ) + 1 mod q ) , … , B ( s ( 2 ) + p - 1 mod q ) \}\end{matrix}$$

wherein s(0)=3, s(1)=7, s(2)=12.

Thus, a first subsequence B_{λ=0} corresponds to the 8 consecutive complex values starting from B(3), a second subsequence B_{λ=1} corresponds to the 8 consecutive complex values starting from B(7), and a third subsequence B_{λ=2} corresponds to the 8 consecutive complex values starting from B(14), modulo q.

In a third step 43, at least one of the selected subsequences B_{λ=0}, B_{λ=1} and B_{λ=2} is used to generate said signal.

For example, each of the selected subsequences can be allocated to a distinct terminal of the communications system and used by the terminal to generate a wanted signal, for example by encoding, spreading or modulating the wanted data with the selected subsequence. This allows a receiver to decorrelate the received signals.

The different subsequences can also form the code words of a dictionary intended to be used for encoding user data.

### 5.2 Construction of the Basic Sequence

Different techniques can be used to construct a basic sequence.

### 5.2.1 Construction in the Frequency Domain, with any c

FIG. 5 illustrates the main steps for constructing a basic sequence in the frequency domain. The basic sequence obtained using this technique can be represented in the complex domain by non-unitary points, i.e. by points that are not all located on the unit circle.

In a first step 51, an initial vector Θ comprising q/c real elements is obtained. It is noted that q is a multiple of c, c>1.

For each real element Θ(k) of the initial vector Θ, the real element Θ(k) is transformed into a complex element Δ(k) in a second step 52, according to the expression:

$$Δ ( k ) = {( cq )}^{1 / 2} {e}^{\frac{2 π j Θ ( k )}{q}} , with k ∈ \{ 0 , ¨ , q / c - 1 \}$$

In a third step 53, a Kronecker product between the vector Δ formed of the complex elements Δ(k) and a binary vector A of size n_{A}=c is determined, such that A(i=h)=1 and A(i=h)=0, wherein i∈{0, . . . , c−1}, and h and c are coprime integers, which provides a basic vector X of size q.

Finally, in a fourth step 54, a transformation of the basic vector X from the frequency domain to the time domain is applied (for example, an Inverse Fast Fourier Transform), which provides the basic sequence B of q complex values.

An example of an algorithm for implementing such a construction method is proposed below:

for k = 0 to q/c − 1
$Δ ( k ) = {( cq )}^{1 / 2} {e}^{\frac{2 π j Θ ( k )}{q}}$
end for;
A = zeros(1, c) (construction of a zero vector of size c)
A(h) = 1 (wherein h is such that h and c are coprime numbers)
X = Kronecker(Δ, A)
B = ifft(X).

According to a first example, for c=3 and q=75, the initial vector Θ of size 25 (75/3) can be chosen by randomly selecting numbers between 0 and q−1=74:
Θ=(8 49 37 58 53 67 66 25 52 14 2 55 37 35 67 45 46 64 60 43 13 17 66 2 36).

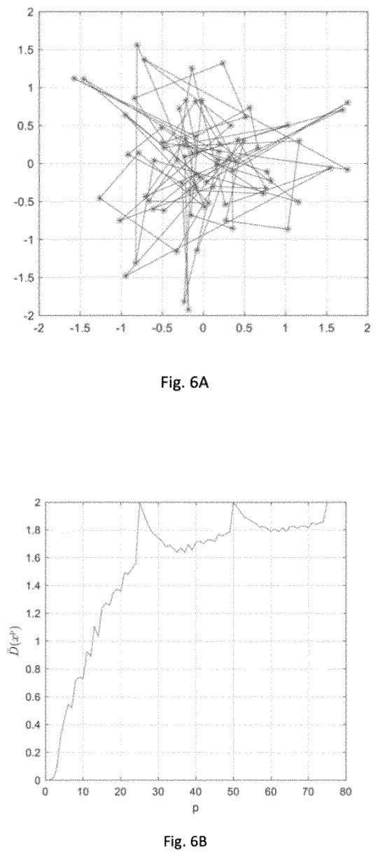

FIG. 6A illustrates the points corresponding to the graphical representations of the q=75 complex values of the basic sequence B obtained with such an initial vector Θ and h=1.

The representation of the autocorrelation function R_{BB} of the basic sequence B in the complex plane has a symmetry of order 3.

FIG. 6B illustrates the progression of the normalized minimum distance D̅(B^{p}) as a function of the size p of the subsequences. If p=q/3=25, if p=2q/3=50, or if p=q=75, the normalized minimum distance is optimal with D̅(B^{p})=2.

According to a second example, for c=5 and q=75, the initial vector Θ of size 15 (75/5) can be chosen by randomly selecting numbers between 0 and q−1=74:

$$Θ = ( 8 \; 49 \; 37 \; 58 \; 53 \; 67 \; 66 \; 25 \; 52 \; 14 \; 2 \; 55 \; 37 \; 35 \; 67 )$$

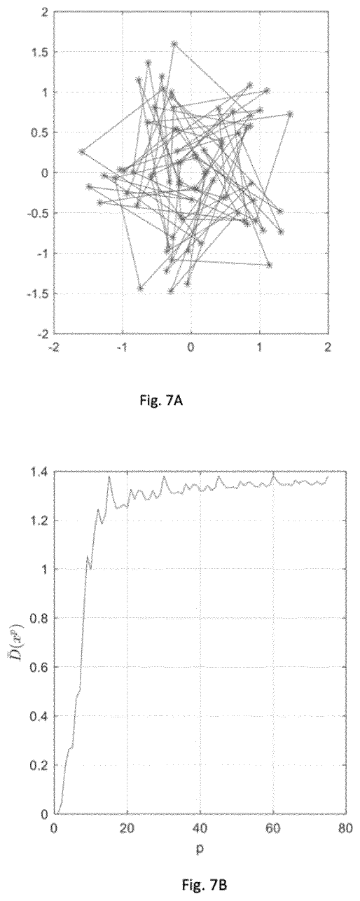

FIG. 7A illustrates the points corresponding to the graphical representations of the q=75 complex values of the basic sequence B obtained with such an initial vector Θ and h=3.

The representation of the autocorrelation function R_{BB} of the basic sequence B in the complex plane has a symmetry of order 5.

FIG. 7B illustrates the progression of the normalized minimum distance D̅(B^{p}) as a function of the size p of the subsequences. If p=q/5=15, if p=2q/5=30, if p=3q/5=45, if p=4q/5=60, or if p=q=75, the normalized minimum distance is optimal with D̅(B^{p})=1.38.

It is noted that the minimum distance D̅(B^{p}) is not equal to 2 in this case, but is slightly less than 1.38.

This corresponds to the minimum distance between two points of a pentagon located on the unit circle, as illustrated in FIG. 7C.

### 5.2.2 Special Case c=4

We now turn to the special case c=4. A basic sequence constructed with c=4 is also called a C4 sequence.

As indicated in the foregoing, the autocorrelation function R_{BB} of a basic sequence B satisfies:

$${R}_{BB} ( τ = iq / 4 ) = {e}^{\frac{2 j π hi}{4}} {R}_{BB} ( 0 ) , for i ∈ \{ 0 , 1 , 2 , 3 \}$$

wherein q is a multiple of 4, h and 4 are coprime numbers, h takes its values from the set {1, 3}, and:

$${R}_{BB} ( τ ) = 0 otherwise .$$

A C4-type (i.e. with c=4) basic sequence B of size q can thus be characterized by its circular autocorrelation function R_{BB}(τ) that satisfies the following property:

$$\{ \begin{matrix}{R}_{BB} ( τ = iq / 4 ) = q \times {j}^{- th} & wherein i ∈ \{ 0 , 1 , 2 , 3 \} and {j}^{2} = - 1 \\ {R}_{BB} ( τ ) = 0 & otherwise\end{matrix}$$

The parameter h allows two types of C4 sequences to be defined: h=1 corresponds to a C4 sequence whose points of the autocorrelation function for τ=iq/4 with i∈{0, 1, 2, 3} are connected in a clockwise direction (“clockwise” C4 sequence), while h=3 corresponds to a C4 sequence whose points of the autocorrelation function for τ=iq/4 with i∈{0, 1, 2, 3} are connected in a counterclockwise direction (“anti-clockwise” C4 sequence). The value of h=3 corresponds to h=−1 because (−1 mod 4)=(3 mod 4).

The graphical representation of the autocorrelation function of the C4-type basic sequence in the complex plane, also known as a C4 constellation, describes a cross centred at 0 that connects the zero point with the points q, jq, −q, −jq, and thus has a symmetry of order 4. The C4 sequence gets its name from the words “Constellation”, “Cross”, “Circular” and “Auto-Correlation”.

Such a C4 sequence makes it possible to obtain a normalized distance D̅(B^{p}) equal to 2 for different values of p, in particular p=q/4, p=q/2, p=3q/4 and p=q.

A generic algorithm for constructing basic sequences in the frequency domain, with any c, has been described in detail in the foregoing. In the following, different techniques for constructing C4 basic sequences are described.

### 5.2.3 Construction of the Basic Sequence by Operational Research, with c=4

According to a first technique, the starting constellation C is defined a priori as an ordered set of q points in the complex plane, C=(C(0), C(1), . . . , C(q−1)), and the basic sequence B is defined by a permutation p of size q that associates the i^{th} element B(i) of the basic sequence B with the complex point C(ρ(i)), i.e. B(i)=C(ρ(i)), for i=0,1, . . . , q−1.

The constellation C can be constructed as C=(C(i)=e^{2jπi/q}, i=0,1, . . . , q−1), for example.

Next, it is necessary to solve a known optimization problem: for a set P of given values of p(P={q/4} or P={1, 2, 3, . . . , q−1}, for example), find the permutation ρₒₚₜ that maximises the sum of the distances D̅(B^{p}), p∈P:

$${ρ}_{opt} = arg {max}_{ρ} ( {\sum }_{p ∈ P} \overline{D} ( {B}^{p} ) ) ,$$

This first technique allows C4 sequences to be found for small sequences (q≤16). For larger sequences (typically q>16), this solution is difficult to implement due to the exponential increase in the size of the solution search space (the number of permutations of a set of q elements in a set of q elements varies as a factorial of q).

### 5.2.4 Construction of the Basic Sequence by Recursion, with c=4

According to a second technique, it is possible to construct C4 sequences so that the points corresponding to the graphical representations of the q complex values of the C4 sequence (constellation) are uniformly distributed over the unit circle, by using a recursion algorithm to determine the phase φ of the points:

### Initialization:

$$\begin{matrix}φ ( 0 ) = 0 \\ Recursion : for i = 1 to q - 1 \\ φ ( i + 1 ) = φ ( i ) \times ( l + 1 ) + a mod q \\ a = 1 or a = - 1 and l = 4.\end{matrix}$$

This gives us the C4 sequence:

$$B ( i ) = {e}^{2 j πϕ ( i ) / q} , i = 0 , 1 , … , q - 1$$

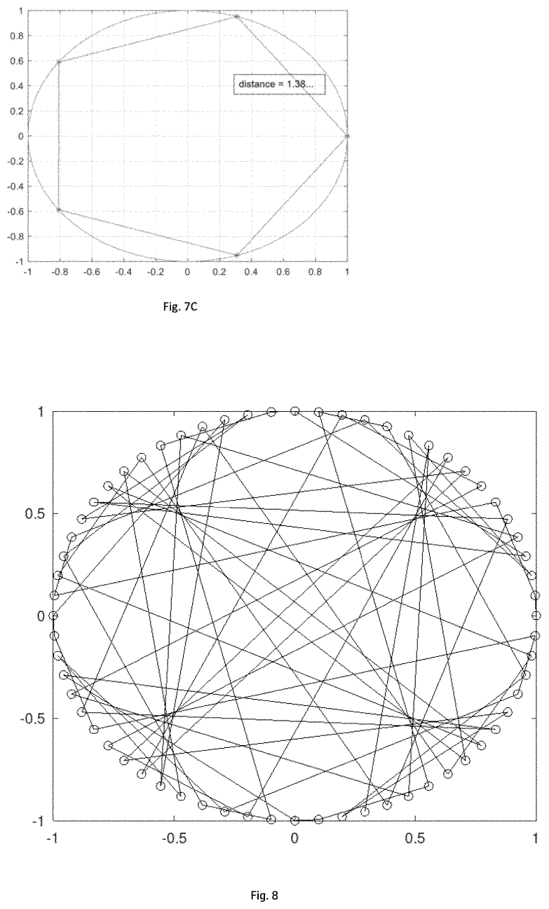

By way of example, FIG. 8 illustrates the representation in the complex plane of the C4 sequence constructed for a=1, l=4 and q=64. Two successive points in the sequence are connected by a line, which forms an epicycloid with 4 cusps.

Other sets of recursions are known, for example, the astroid defined by the recursion φ(i+1)=(−φ(i)×(l−1)+a)mod q or by the recursion φ(i+1)=φ(i)+4×i+1 mod q.

It is also possible to modify this recursion in order to decrease the number of points in the constellation while still maintaining a C4 constellation. For example, to go from a 64-PSK constellation (regular constellation with 64 points) to a constellation with 32 points (half as many points) or 16 points (a quarter as many points), it is sufficient to transform the sequence with the following function:

$${φ}^{′} ( i ) = a ⌊ \frac{φ}{a} ⌋$$

wherein a=2 and a=4, respectively.

### 5.2.5 Construction of the Basic Sequence in the Time Domain, with c=4

According to a third technique, it is possible to construct C4 sequences in the time domain.

An example of an algorithm is described in the following that can be implemented to generate a class of C4 sequences of length q, wherein q is a multiple of 4, such that the points corresponding to the graphical representations of the q complex values of a C4 sequence are on the unit circle.

The input considered here is thus an offset vector O of size 4 that takes its values from between 0 and q−1 (this condition is sufficient to obtain a C4 sequence with points located on the q-PSK constellation defined by the set {e^{2kπj/q}, k=0, 1, . . . , q−1}, but it is not a necessary condition, however, and this constraint is indicated solely by way of example), p is a permutation of the set (1, 2, 3, 4), and d is a variable that takes either the value +1 or −1.

From these inputs, the following algorithm generates a unitary C4 sequence B of size q:

```
$M ( 0 ) = 0 ; M ( 1 ) = \frac{q}{4} ; M ( 2 ) = \frac{q}{2} ; M ( 3 ) = \frac{3 q}{4} ;$
for k = 0 q/4 − 1
  for i = 0: 3
    $φ ( 4 \times k + i ) = O ( i ) + k \times ( 4 + 8 d + M ( ρ ( i ) ) )$
  end for
end for
φ = φ mod q
for i = 0 to q − 1
  $B ( i ) = {e}^{2 π j φ ( i ) / q}$
end for.
```

### 5.2.6 Construction of the Basic Sequence in the Frequency Domain, with c=4

According to a fourth technique, it is possible to construct C4 sequences in the frequency domain, as explained in relation to the general case with any c.

In the following, an example of an algorithm is described that can be implemented to generate a class of C4 sequences of length q, wherein q is a multiple of 4, such that the points corresponding to the graphical representations of the q complex values of a C4 sequence are located on the unit circle or not.

The input considered here has a size q, an initial vector Θ comprising

$$\frac{q}{4}$$

real elements, while h is a variable that takes either the value +1 to generate a “clockwise” C4 sequence, or −1 to generate an “anti-clockwise” C4 sequence.

From these inputs, the following algorithm generates a unitary or non-unitary C4 sequence B of size q, noted as X, in the frequency domain:
for k=0 to q/4−1

$$Δ ( k ) = {( 4 q )}^{1 / 2} {e}^{\frac{2 π j Θ ( k )}{q}}$$

end for;

$$A = [ \begin{matrix}0 & \frac{1 + h}{2} & 0 & \frac{1 - h}{2} ]\end{matrix}$$

$$X = Kronecker ( Δ , A )$$

$$B = ifft ( X ) .$$

For c=4, the binary vector A is either equal to [0 1 0 0] if h=+1, or equal to [0 0 0 1] if h=−1. As already indicated, (−1 mod 4)=(3 mod 4).

This technique in particular makes it possible to construct non-unitary constellations.

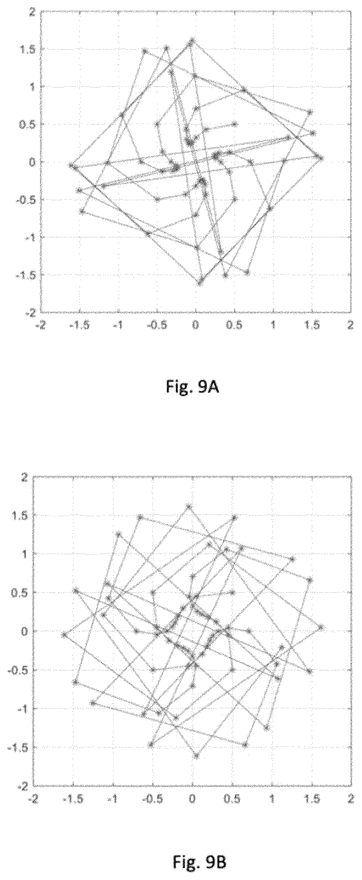

By way of example, FIGS. 9A and 9B illustrate the graphical representations of the C4 sequences obtained for q=64, an initial vector Θ=(Θ(i)=i², i=0, 1, . . . , 15), and h=+1 for FIG. 9A, or h=−1 for FIG. 9B.

A C4 sequence constructed with a random initial vector Θ is not necessarily unitary, i.e. the points associated with its graphical representation in the form of a constellation are not necessarily located on a circle.

However, it is possible to constrain the choice of real values for the initial vector Θ so that the C4 sequence is unitary by design.

Conversely, all unitary sequences already found can be constructed from a specific initial vector Θ. In order to obtain a unitary C4 sequence, according to a first example, if q=2^{2t}, with t>1, the q/4 real elements of the initial vectorΘ can be chosen such that:

$$Θ ( {2}^{t - 1} u + r ) = d ( r ) + u γ ( r ) {2}^{t + 1}$$

wherein:
d is a real vector of size 2^{t-1}. We note that there are no constraints regarding the construction of the vector d. It can be chosen randomly or optimized according to a criterion specific to the application. For example, it is possible to consider optimizing the normalized distance D̅(B^{p}) for particular values of p. For instance, p=1 will make it possible to generate a C4 sequence associated with a constellation in which the minimum distance between two points of the constellation will be maximized;
γ is a permutation of the set (0, 1, . . . , 2^{t-1}−1),
0≤r<2^{t-1} and 0<u<2^{t-1}.

According to a second example, if q=2^{2t+1}=2⁵, with t=2, the q/4 real elements of the initial vector Θ can be chosen such that:

$$Θ ( ρ ( 0 ) ) = d ( ρ ( 0 ) )$$

$$Θ ( ρ ( 1 ) ) = d ( ρ ( 1 ) )$$

$$Θ ( 2 + ρ ( 0 ) ) = d ( ρ ( 0 ) ) + {2}^{t + 1} {ϵ}_{0}$$

$$Θ ( 2 + ρ ( 1 ) ) = d ( ρ ( 1 ) + {2}^{t + 1} ( 1 - {ϵ}_{1} )$$

$$Θ ( 4 + ρ ( 0 ) ) = d ( ρ ( 0 ) )$$

$$Θ ( 4 + ρ ( 1 ) ) = d ( ρ ( 1 ) ) + {2}^{t + 2} )$$

$$Θ ( 6 + ρ ( 0 ) ) = d ( ρ ( 0 ) ) + {2}^{t - 1} {ϵ}_{0}$$

$$Θ ( 6 + ρ ( 1 ) ) = d ( ρ ( 1 ) ) + {2}^{t + 1} ( 1 + {ϵ}_{1} )$$

wherein:
d is a real vector of size 2^{t-1}. Again, there are no constraints regarding the construction of the vector d. It can be chosen randomly or optimized according to a criterion specific to the application. For example, it is possible to consider optimizing the normalized distance D̅(B^{p}) for particular values of p. For instance, p=1 will make it possible to generate a C4 sequence associated with a constellation in which the minimum distance between two points of the constellation will be maximized;
ρ is a permutation of the set (0,1) (ρ=(0,1) or ρ=(1,0)),
(∈₀, ∈₁)∈{−1,1}².

According to a third example, if q=2^{2t+1}=2⁷, with t=2, the q/4 real elements of the initial vector Θ can be chosen such that:

$$Θ ( i \& 28 + ρ ( 0 ) ) = d ( ρ ( 0 ) ) + 32 {ϵ}_{0} {i}_{2}$$

$$Θ ( i \& 28 + ρ ( 1 ) ) = d ( ρ ( 1 ) ) + 64 ( {i}_{2} \frac{1 + {ϵ}_{1}}{2} ) ⊕ {i}_{3}$$

$$Θ ( i \& 28 + ρ ( 2 ) ) = d ( ρ ( 2 ) ) + 16 ( 3 + 2 {ϵ}_{2} ) {i}_{2} + 96 {( {i}_{4} {i}_{3} )}_{2}$$

$$Θ ( i \& 28 + ρ ( 3 ) ) = d ( ρ ( 3 ) ) + 16 ( 5 + 2 {ϵ}_{3} ) {i}_{2} + 32 {( {i}_{4} {i}_{3} )}_{2}$$

$$wherein :$$

$$i \& 28 = i - ( i mod 4 ) ,$$

$${( {i}_{4} {i}_{3} )}_{2} = 2 {i}_{4} + {i}_{3} ,$$

d is a real vector of size 2^{t-1}. Again, there are no constraints regarding the construction of the vector d,
ρ is a permutation of the set (0, 1, 2, 3),

$${( {ϵ}_{i} )}_{i = 0 , 1 , 2 , 3} ∈ {\{ - 1 , 1 \}}^{4} .$$

### 5.2.7 Construction of the Basic Sequence in the Frequency Domain that Minimizes D̅(B), with c=4

A modified initial vector Θ′ can in particular be obtained from an initial vector Θ with which it is possible to obtain a unitary C4 sequence so that the points corresponding to the graphical representations of the q complex values of a basic sequence obtained from the modified initial vector correspond to the points of a constellation diagram of a q-APSK modulation. In particular, it is possible to apply the frequency method in order to generate a q-APSK constellation and an associated C4 sequence that maximizes the distance D̅(B¹), i.e. the minimum distance between two points in the constellation.

The modified initial vector Θ′ can in particular be obtained by adding an added vector V of size q/c and the initial vector Θ of q/c real elements, such that the added vector V is equal to ν×N, wherein ν∈[1,q−1] and N is a vector of size q/c constructed by choosing its q/(2c) first coordinates in the set {−1,0,1}, then copying the q/(2c) first coordinates so that N(i)=N(i+q/(2c)), i=0,1, . . . , q/(2c)−1.

An example of an algorithm is described in the following that makes it possible to obtain a basic sequence that minimizes the distance D̅(B¹) from a unitary basic sequence. By way of example, c=4 and q=64 here. It is noted, however, that the proposed algorithm can be generalized to different values of c or lengths q of the sequence.

The input considered here is thus a unitary C4 sequence of size q=64, noted as B.

In a first step, the vector representing the unitary C4 sequence B is transformed from the time domain to the frequency domain:

$$X = fft ( B ) .$$

It is then attempted to extract, from the thus obtained basic vector X, the initial vector Θ comprising

$$\frac{q}{c} = \frac{64}{4} = 16$$

real elements (used to construct the sequence B), by determining the phrases of the 16 non-zero coefficients (coefficients located at indices equal to h mod 4, wherein h=+1 for a “clockwise” sequence and h=−1 for an “anti-clockwise” sequence).

In a subsequent step, the initial vector Θ is modified by adding to it a vector V (added vector) of size 16 which is defined as follows:

$$V = v \times N = v \times [ N ( 0 ) , N ( 1 ) , N ( 2 ) , N ( 3 ) , N ( 4 ) , N ( 5 ) , N ( 6 ) , N ( 7 ) , N ( 0 ) , N ( 1 ) , N ( 2 ) , N ( 3 ) , N ( 4 ) , N ( 5 ) , N ( 6 ) , N ( 7 ) ] ,$$

wherein ν∈[1, q−1] is a real number that can take, for example, integer values in the interval [1, 63] and the coefficients N(i) take their values from −1, 0 or 1.

This makes it possible to obtain a modified initial vector Θ′=Θ+V, and to subsequently construct a new sequence B′ using the technique for constructing C4 sequences in the frequency domain described in the foregoing from the modified initial vector Θ′.

It is then possible to determine the value of D̅(B^{′1}) in the thus created sequence. It then suffices to generate different sequences B′ and to keep only the one that maximizes D̅(B^{′1}).

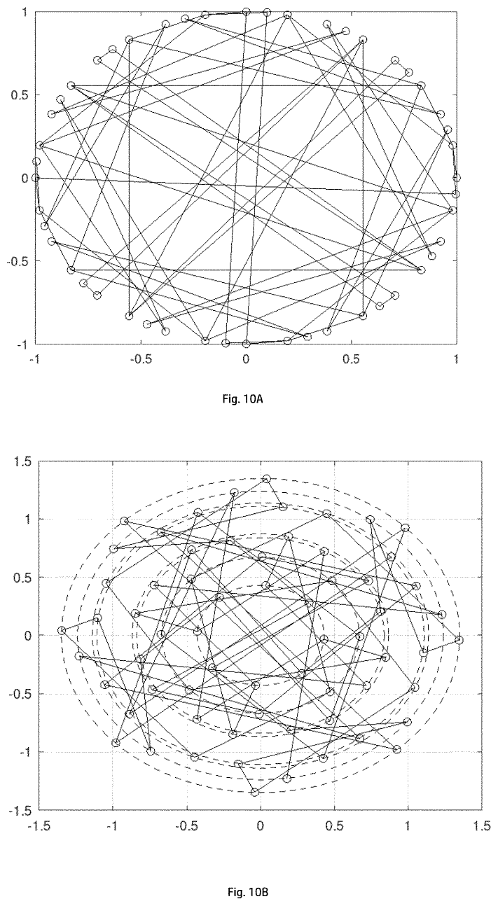

By way of example, the input considered here is a unitary C4 sequence of size q=64, noted as B, which is obtained using the frequency method from an initial vector Θ=(0,61,52,44,0,45,20,60,0,29,52,12,0,13,20,28) and h=+1, which yields the unitary C4 sequence illustrated in FIG. 10A.

When ν=18 and N=(−1,+1,0, +1,0,−1,+1,−1), the added vector V is equal to:

$$V = ( - 18 , + 18 , 0 , + 18 , 0 , - 18 , + 18 , - 18 , - 18 , + 18 , 0 , + 18 , 0 , - 18 , + 18 , - 18 )$$

Adding the added vector and the initial vector yields:

$${Θ}^{′} = Θ + V = ( - 18 , 79 , 52 , 62 , 0 , 27 , 38 , 42 , - 18 , 47 , 52 , 30 , 0 , - 5 , 38 , 10 ) .$$

The thus modified initial vector and the variable h=+1 can then be used to generate a new sequence B′ such as the non-unitary C4 sequence illustrated in FIG. 10B.

For example, the thus constructed sequence B′ has a minimum distance D̅(B′)=6,12×10⁻².

### 5.3 Example Applications

### 5.3 Construction of Orthogonal Basic Sequences

As indicated in the foregoing, the thus constructed basic sequences can in particular be spreading sequences intended for use by distinct terminals, or groups of terminals, of a communications system. Indeed, in a multi-user context, it is advantageous to associate specific sequences with users (or groups of users) in order to facilitate multi-user detection.

In particular, it is possible to choose a “clockwise” C4 sequence (with h=+1), noted as x, and an “anti-clockwise” C4 sequence (with h=−1), noted as y. These two types of sequences are, by design, orthogonal to each other. Indeed, the calculation of the intercorrelation between the sequences x and y in the frequency domain yields:

$${R}_{x y} = ifft ( fft ( x ) \cdot {fft ( y )}^{*} ) = 0$$

As X=fft(x) has non-zero frequencies at the indices k=1 mod 4, while Y=fft(y) has non-zero frequencies at the indices k=3 mod 4, it is thus possible to deduce that R_{xy}(τ)=0 for all values of τ.

### 5.3.2 Identification by Subsequences of Size p

In a multi-user context, it can also be advantageous to associate subsequences of size p with users (or groups of users) in order to facilitate multi-user detection. For example, a basic sequence of size q can be truncated into at least one subsequence of size p.

By way of example, a communications system with q=4p users (or groups of users) is considered in which one wishes to associate each user with a sequence of size p that allows the users to identify themselves in a multi-user protocol. It is in particular possible to construct a C4 sequence x of size q and to associate the kth user (or group of users) with the sequence of size p defined by

$${x}_{k}^{p} .$$

Indeed, it can be shown that:
if (k−l)≠0 mod p, then

$$〈 {x}_{k}^{p} , {x}_{l}^{p} 〉$$

<<q,
if l=k+2p mod q, then

$$〈 {x}_{k}^{p} , {x}_{l}^{p} 〉 = - p ,$$

and therefore, according to the equation

$${d ( {B}_{a}^{p} , {B}_{b}^{p} )}^{2}$$

$${d ( {x}_{k}^{p} , {x}_{k + 2 q}^{p} )}^{2} = {‖ {x}_{k}^{p} ‖}^{2} + {‖ {x}_{k + 2 p}^{p} ‖}^{2} + 2 p$$

if l=k+p mod q or l=k+3p mod q, then

$$〈 {x}_{k}^{p} , {x}_{l}^{p} 〉$$

=±jp, and therefore, according to the equation,

$${d ( {B}_{a}^{p} , {B}_{b}^{p} )}^{2} = {‖ {x}_{k}^{p} ‖}^{2} + {‖ {x}_{k + 2 p}^{p} ‖}^{2} - 2 ℛ ( 〈 {B}_{a}^{p} , {B}_{b}^{p} 〉 ) :$$

$${d ( {x}_{k}^{q} , {x}_{k + 2 q}^{q} )}^{2} = 2 q - 2 ℛ ( 〈 {x}_{k}^{q} , {x}_{k + 2 q}^{q} 〉 ) = 2 q .$$

This amounts to showing that p=q/4 and for each k,

$${x}_{k}^{p} = - {x}_{k + 2 p}^{p} , {x}_{k}^{p} = {j}^{h} {x}_{k + p}^{p} , {x}_{k}^{p} = {j}^{- h} {x}_{k + 3 p}^{p}$$

wherein h indicates the direction of rotation of the C4 sequence (thus, j^{h}=j and j^{-h}=−j if h=1, and j^{h}=−j and j^{-h}=j if h=−1).

This subsampling technique can naturally be extended to other sequence lengths (in particular, p=q/2 or p=3q/4, or other values of p). In addition, the number of allocated sequences can be less than q.

For example, such a system is advantageous for initiating communication in a cellular network between a mobile device and a base station.

### 5.3.3 Identification by Orthogonal Subsequences and Sequences

It is in particular possible to increase the number of users, or groups of users, in a communications system by combining the use of subsequences of size p and orthogonal basic sequences or subsequences (i.e. with a large distance between each sequence) so as to increase the number of users that can be easily distinguished from one another.

Different examples are explained in the following.

According to a first example, for q=p, it is possible to generate 2q sequences of size p=q from two C4 sequences x and y of size q, wherein h=+1 for the sequence x, and h=−1 for the sequence y. The 2q identifiers/spreading sequences of size p=q can then be defined by the union of the q sequences {xₐ, a=0,1, . . . , q−1} and {y_{b}, b=0,1, . . . , q−1}.

It is in particular possible to choose the C4 sequences x and y so that the distance between discriminated sequences is equal to 2q, thus allowing an effective separation of users from one another.

By way of example, for q=64, it is possible to define what is known as an epicyloid sequence x with a=+1 and an epicycloid sequence y with a=−1. This allows the creation of a set of 128 sequences of size 64 with a normalized distance between two distinct sequences equal to 2.

According to a second example, for q=2p, it is possible to generate 4p=2q sequences of size

$$p = \frac{q}{2}$$

from two C4 sequences x and y of size q, wherein h=+1 for the sequence x and h=−1 for the sequence y. The 2q identifiers/spreading sequences of size p=q/2 can then be defined by the union of the q sequences

$$\{ {x}_{a}^{p} , a = 0 , 1 , … , d - 1 \} and \{ {y}_{b}^{p} , b = 0 , 1 , … , q - 1 \} .$$

It is also possible to choose the C4 sequences x and y so that the distance between two discriminated sequences is equal to q, which enables an effective separation of users from one another.

By way of example, for q=64, it is possible to define the sequence x from the initial vector Θ=(46, 62, 0, 38, 14, 62, 0, 6, 46, 62, 0, 38, 14, 62, 0, 6) and h=+1, and the sequence y from the initial vector Θ=(42, 44, 0, 38, 10, 44, 0, 6, 42, 44, 0, 38, 10, 44, 0, 6) and h=−1 in order to obtain this property. This allows the creation of a set of 128 sequences of size 32, with a normalized distance between two distinct sequences equal to 2.

According to a third example, for q=4p, it is possible to generate 4p=q sequences or size

$$p = \frac{q}{2}$$

from two C4 sequences x and y of size q, wherein h=+1 for the sequence x and h=−1 for the sequence y. The 2q identifiers/spreading sequences of size

$$p = \frac{q}{2}$$

can then be defined by the union of the q sequences

$$\{ {x}_{a}^{p} , a = 0 , 1 , … , d - 1 \} and \{ {y}_{b}^{p} , b = 0 , 1 , … , q - 1 \} .$$

In this case, it is also possible to choose the C4 sequences x and y that make it possible to maximize the minimum distance between two sequences. For example, for q=64, it is possible to define the sequence x from the initial vector Θ=(1,2,3,4,1,18,35,52,1,34,67,100,1,50,99,14) and h=−1.

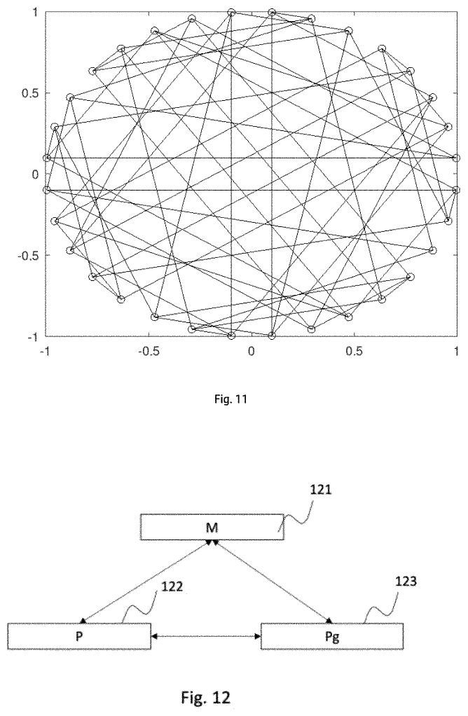

The resulting sequence is illustrated in FIG. 11.

To generate the sequence in the inverse direction, it is possible to define \hat{x}(i)=x(q−i), i=0,1, . . . , q−1, with the operations on the indices being performed modulo q.

The (non-normalized) minimum distance between two subsequences of the basic sequence x and the basic sequence \hat{x} is 14.5. In other words, regardless of the value of a and b,

$${d ( {x}_{a}^{p} , {\hat{x}}_{b}^{p} )}^{2} \geq 14.5 .$$

It is of course possible to use two sequences constructed with a random initial vector and h=+1 and h=−1. The minimum distance remains approximately the same.

### 5.3.4 Coding Scheme

As indicated in the foregoing, the thus constructed basic sequences can also define code words of a dictionary intended for use by an encoder in said communications system.

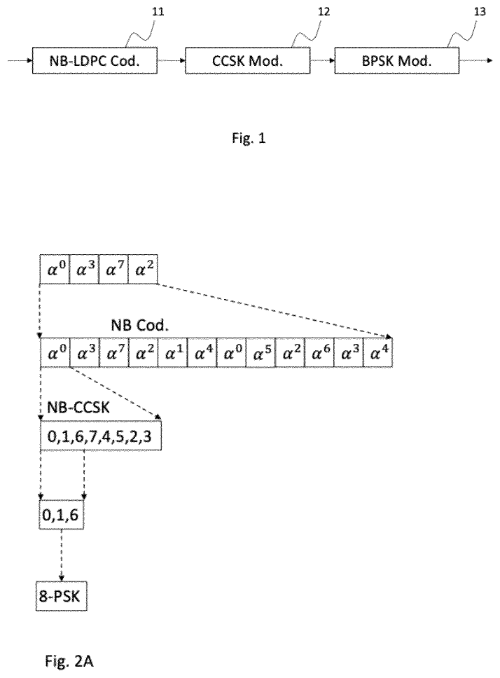

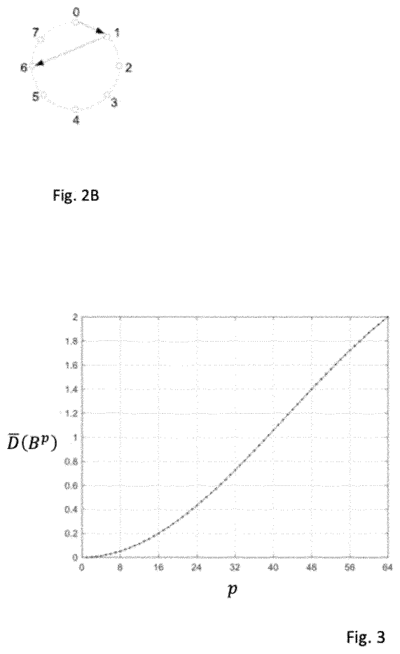

In particular, such basic sequences can be used in a coding scheme that associates a binary or non-binary error-correcting code with a cyclic code-shift keying (CCSK) modulation, as illustrated in FIG. 1, or in a coding scheme that associates a binary or non-binary code with a truncated binary or non-binary CCSK modulation, as illustrated in FIG. 2A.

### 5.3.5 Other Example Applications

Although motivated by the efficient NB-TCCSK coding scheme design, the proposed basic sequences, in particular the C4 sequences, can also be used in other fields of application. In particular, such sequences can be used instead of Zadoff-Chu sequences, for example in 5G protocols.

### 5.4 Corresponding Device

Finally, in relation to FIG. 12, the simplified structure of an entity of a communications system is described that implements a technique for generating a signal according to one of the particular embodiments described above.

Such an entity includes a memory 121 including a buffer memory, a processing unit 122, which is equipped, for example, with a processor P and which is controlled by the computer program 123, which implements the method for generating a signal according to an embodiment.

Upon initialization, the code instructions of the computer program 123 are, for example, loaded into a RAM memory before being executed by the processor of the processing unit 122. The processor of the processing unit 122 implements the steps of the method described in the foregoing, according to the instructions of the computer program 123, in order to:
obtain a basic sequence of q complex values, noted as B, such that the autocorrelation function R_{BB} of said basic sequence B, which is defined by

$${R}_{BB} ( τ ) = {\sum }_{n = 0}^{q - 1} B ( n ) B ( ( n + τ ) mod q ) * ,$$

wherein B((n+τ)mod q)* denotes the complex conjugate of B((n+τ)mod q) and τ=0,1, . . . , q−1, satisfies:

$${R}_{BB} ( τ = iq / c ) = {e}^{- \frac{2 j π hi}{c}} {R}_{BB} ( 0 ) , for i ∈ \{ 0 , … , c - 1 \}$$

wherein q is a multiple of c, c>1, h and c are coprime integers, and j²=−1,
and:

$${R}_{BB} ( τ ) = 0 otherwise ,$$

select Λ subsequences of p complex values in said basic sequence B, such that said subsequence λ, noted as B_{λ}=B^{p}(s(λ)), wherein λ∈{0, . . . , Λ−1}, 1≤Λ, is equal to:

$${B}_{λ} = \{ B ( s ( λ ) ) , B ( s ( λ ) + 1 mod q ) , … , B ( s ( λ ) + p - 1 mod q ) \}$$

wherein s(λ) is an integer belonging to {0, . . . , q−1} corresponding to a position in said basic sequence B, and B(s(λ)) is the complex value associated with said position s(λ) in said basic sequence B,
use at least one of said selected subsequences to generate said signal.

Such an entity, or a separate entity, can also implement a technique for constructing such a basic sequence.

1. A method for generating a signal which is implemented by a device in a digital communications system and which comprises:
obtaining a basic sequence of q complex values, noted as B, such that the autocorrelation function R_{BB} of said basic sequence B, which is defined by
$${R}_{B B} ( τ ) = {\sum }_{n = 0}^{q - 1} B ( n ) {B ( n + τ mod q )}^{*} ,$$
wherein B((n+τ)mod q)* denotes the complex conjugate of B((n+τ)mod q), and τ=0,1, . . . , q−1, satisfies:
$${R}_{B B} ( τ = i q / c ) = {e}^{- \frac{2 j π h i}{c}} {R}_{B B} ( 0 ) , for i ∈ \{ 0 , … , c - 1 \}$$
wherein q is a multiple of c, c>1, h and c are coprime integers, and j²=−1,
and:
$${R}_{B B} ( τ ) = 0 otherwise ;$$
selecting Λ subsequences of p (consecutive) complex values in said basic sequence B, such that said subsequence λ, noted as B_{λ}=B^{p}(s(λ)), wherein λ∈{0, . . . , Λ−1}, 1≤Λ, is equal to:
$${B}_{λ} = \{ B ( s ( λ ) ) , B ( s ( λ ) + 1 mod q ) , … , B ( s ( λ ) + p - 1 mod q ) \}$$
wherein s(λ) is an integer belonging to {0, . . . , q−1} corresponding to a position in said basic sequence B, and B(s(λ)) is the complex value associated with said position s(λ) in said basic sequence B; and
using at least one of said selected subsequences to generate said signal.

2. The method according to claim 1, wherein said subsequences are spreading sequences intended for use by distinct terminals, or groups of terminals, of the communications system.

3. The method according to claim 1, wherein the method comprises allocating one of said selected subsequences to a terminal of said communications system and of transmitting said signal using said subsequence.

4. The method-according to claim 1, wherein said subsequences are code words of a dictionary intended to be used by an encoder of said communications system.

5. The method according to claim 4, wherein the method implements an association of at least one coded symbol, obtained at an end of encoding at least one source symbol, with one of said selected subsequences.

6. The method according to claim 1, wherein said basic sequence B is obtained based:
obtaining an initial vector Θ comprising q/c real elements,
for each real element Θ(k) of said initial vector Θ, transforming said real element Θ(k) into a complex element Δ(k), according to the expression:
$$Δ ( k ) = {( c q )}^{1 / 2} {e}^{\frac{2 π j Θ ( k )}{q}} , wherein k ∈ \{ 0 , … , q / c - 1 \} and {j}^{2} = - 1 ,$$
determining a Kronecker product between the vector Δ formed from said complex elements Δ(k) and a binary vector A of size n_{A}=c, such that A(i=h)=1 and A(i≠h)=0, wherein i∈{0, . . . , c−1}, h and c are coprime integers, which provides a basic vector X of size q,
transforming said basic vector X from the frequency domain to the time domain, which provides said basic sequence B of q complex values.

7. The method-according to claim 6, wherein said q/c real elements of said initial vector Θ are chosen randomly.

8. The method according to claim 6, wherein said q/c real elements of said initial vector Θ are chosen so that the points corresponding to the graphical representations of the q complex values of said basic sequence B belong to at least one circle.

9. The method according to claim 6, wherein said q/c real elements of said initial vector Θ are chosen so that the points corresponding to the graphical representations of the q complex values of said basic sequence B correspond to the points of a constellation diagram of a q-PSK or q-APSK modulation.

10. The method according to claim 6, wherein c=4 and a modified initial vector Θ′ is obtained by adding a vector V of size q/c, which is known as an added vector, and said initial vector Θ of q/c real elements, wherein said added vector V is equal to ν×N, wherein ν∈[1, q−1] and N is a vector of size q/c constructed by choosing its q/(2c) first elements in the set {−1,0,1}, then copying the q/(2c) first elements so that N(i)=N (i+q/(2c)), i=0,1, . . . , q/(2c)−1.

11. The method according to claim 1, wherein said selecting selects a subset of subsequences, noted as B^{λ}, of cardinality Λ, from the set B^{p} of subsequences of size p, such that said subset B^{λ} has the largest normalized minimum distance D̅(B^{λ}):
$$\overline{D} ( {B}^{λ} ) = \frac{{‖ {B}_{{λ}_{1}} ‖}^{2}}{p} + \frac{{‖ {B}_{{λ}_{2}} ‖}^{2}}{p} - \frac{2}{p} \times {max}_{{λ}_{1} , {λ}_{2} , {λ}_{1} \neq {λ}_{2}} \{ ℛ ( 〈 {B}_{{λ}_{1}} , {B}_{{λ}_{2}} 〉 ) \}$$
wherein [symbol] ( [symbol] B_{λ}_{₁}, B_{λ}_{₂} [symbol] ) denotes the real part of the expression of the scalar product between the subsequence B_{λ}_{₁} and the subsequence B_{λ}_{₂},λ₁,λ₂ ∈{0, . . . , Λ−1}².

12. The method according to claim 1, wherein c is equal to 3, 4 or 5.

13. A method comprising:
constructing a basic sequence of q complex values, noted as B, intended for use in a digital communications system and implemented by a processor of a device, wherein an autocorrelation function R_{BB} of said basic sequence B, which is defined by
$${R}_{B B} ( τ ) = {\sum }_{n = 0}^{q - 1} B ( n ) {B ( ( n + τ ) mod q )}^{*} ,$$
wherein B((n+τ)mod q)* denotes the complex conjugate of B((n+τ)mod q), and τ=0,1, . . . , q−1, satisfies:
$${R}_{B B} ( τ = i q / c ) = {e}^{- \frac{2 j π h i}{c}} {R}_{B B} ( 0 ) , for i ∈ \{ 0 , … , c - 1 \}$$
wherein q is a multiple of c, c>1, h and c are coprime integers, and j²=−1,
and:
$${R}_{B B} ( τ ) = {\sum }_{n = 0}^{q - 1} B ( n ) B ( ( n + τ ) mod q ) = 0 otherwise .$$

14. A device for generating a signal, which is implemented in a digital communications system and which comprises:
at least one processor configured to:
obtain a basic sequence of q complex values, noted as B, such that the autocorrelation function R_{BB} of said basic sequence B, which is defined by
$${R}_{B B} ( τ ) = {\sum }_{n = 0}^{q - 1} B ( n ) {B ( ( n + τ ) mod q )}^{*} ,$$
wherein B((n+τ)mod q)* denotes the complex conjugate of B((n+τ)mod q) and τ=0,1, . . . , q−1, satisfies:
$${R}_{B B} ( τ = i q / c ) = {e}^{- \frac{2 j π h i}{c}} {R}_{B B} ( 0 ) , for i ∈ \{ 0 , … , c - 1 \}$$
wherein q is a multiple of c, c>1, h and c are coprime integers, and j²=−1,
and:
$${R}_{B B} ( τ ) = 0 otherwise ;$$
select Λ subsequences of p complex values in said basic sequence B, such that said subsequence λ, noted as B_{λ}=B^{p}(s(λ)), wherein 2 ∈{0, . . . , Λ−1}, 1≤Λ, is equal to:
$${B}_{λ} = \{ B ( s ( λ ) ) , B ( s ( λ ) + 1 mod q ) , … , B ( s ( λ ) + p - 1 mod q ) \}$$
wherein s(λ) is an integer belonging to {0, . . . , q−1} corresponding to a position in said basic sequence B, and B(s(λ)) is the complex value associated with said position s(λ) in said basic sequence B₇; and
use at least one of said selected subsequences to generate said signal.

15. A non-transitory computer readable medium comprising a computer program product stored thereon comprising program code instructions which implementing the method according to claim 1 when the instructions are executed by at least one processor of the device.
